(19) United States
(12) Patent Application Publication
(10) Pub. No.: US 2023/0295415 A1
(43) Pub. Date: Sep. 21, 2023

(54) HIGH-GLOSSINESS EPOXY MOLDING COMPOUND (EMC) FILM FOR PROTECTING CHIP AND PREPARATION METHOD THEREOF

(71) Applicant: WUHAN CHOICE TECHNOLOGY CO., LTD., Wuhan (CN)

(72) Inventors: De WU, Wuhan (CN); Shuhang LIAO, Wuhan (CN); Junxing SU, Wuhan (CN); Feifei LIANG, Wuhan (CN)

(73) Assignee: WUHAN CHOICE TECHNOLOGY CO., LTD., Wuhan (CN)

(21) Appl. No.: 18/201,199

(22) Filed: May 24, 2023

Related U.S. Application Data
(63) Continuation-in-part of application No. PCT/CN2020/132762, filed on Nov. 30, 2020.

(30) Foreign Application Priority Data
Nov. 26, 2020 (CN) 202011356815.5

(51) Int. Cl. C08L 63/00

(52) U.S. Cl. CPC C08L 63/00; C08L 2205/02

(57) ABSTRACT

A high-glossiness epoxy molding compound (EMC) film for protecting a chip and a preparation method thereof are disclosed. The high-glossiness EMC film for protecting a chip includes: 40 to 100 parts by mass of an epoxy resin; 2 to 5 parts by mass of glass epoxy; 45 to 55 parts by mass of fused silica; and 1 to 5 parts by mass of a curing system, where the fused silica has a particle size D50 of 0.15 μm to 0.6 μm. The glossiness of the protective film of the present disclosure is significantly improved, such that the clarity of characters inscribed by a laser under a bright field of a microscope can be further improved, which allows a device to effectively recognize the characters.

### CROSS REFERENCE TO THE RELATED APPLICATIONS

This application is a continuation-in-part application of International Application No. PCT/CN2020/132762, filed on Nov. 30, 2020, which is based upon and claims priority to Chinese Patent Application No. 202011356815.5, filed on Nov. 26, 2020, the entire contents of which are incorporated herein by reference.

### TECHNICAL FIELD

The present disclosure belongs to the technical field of films for protecting electronic chips, and specifically relates to a high-glossiness epoxy molding compound (EMC) film for protecting a chip and a preparation method thereof.

### BACKGROUND

In order to ensure that an electronic chip has a specified strength, a protective film needs to be adhered to the back of the electronic chip with a circuit on its surface. In order to achieve product traceability and unified management of models and trademarks, laser inscription is required on the protective film. However, the traditional film for protecting a chip used by a company has low glossiness, and characters inscribed by a laser on the film are dull under a bright field of a microscope, where there is a poor contrast between a dark background and black characters, and inscribed characters are unclear (as shown in FIG. 3), such that a device is difficult to effectively identify the characters.

### SUMMARY

An objective of the present disclosure is to provide a high-glossiness EMC film for protecting a chip and a preparation method thereof.

The present disclosure provides a high-glossiness EMC film for protecting a chip, including the following components:
epoxy resin: 40 to 100 parts by mass;
glass epoxy: 2 to 5 parts by mass;
fused silica: 45 to 55 parts by mass; and
curing system: 1 to 5 parts by mass,
where the fused silica has a particle size D50 of 0.15 μm to 0.6 μm.

Further, the fused silica preferably has a particle size D50 of 0.27 pin to 0.6 pin.

Further, the epoxy resin is one or more selected from the group consisting of a polyether epoxy resin, a bisphenol F (BPF) epoxy resin, and a polyurethane (PU)-modified bisphenol A (BPA) epoxy resin, and is preferably a polyether epoxy resin.

Further, the curing system includes an accelerating agent and a curing agent, where the curing agent is one or more selected from the group consisting of an amine curing agent, a mercaptan curing agent, an anhydride curing agent, and a phenolic resin curing agent and the accelerating agent is an imidazole accelerating agent.

The accelerating agent and the curing agent can be added according to conventional amounts. In the present disclosure, the accelerating agent is preferably used in 0.1 to 1 part by mass and the curing agent is preferably used in 1 to 4 parts by mass.

Further, the curing agent is preferably dicyanodiamide (DCD), and the accelerating agent is preferably 2-methyl-4-ethylimidazole.

Further, the high-glossiness EMC film for protecting a chip further includes 1 to 5 parts by mass of a colorant.

The present disclosure also provides a preparation method of the high-glossiness EMC film for protecting a chip, including:
(1) mixing 40 to 100 parts by mass of the epoxy resin, 45 to 55 parts by mass of the fused silica, and 1 to 5 parts by mass of the curing system, and stirring a resulting mixture;
(2) adding 2 to 5 parts by mass of the glass epoxy, stirring a resulting mixture, and degassing until a resulting slurry is free of bubbles; and
(3) coating the slurry on a release film, and oven-drying.

Further, in step (1), 1 to 5 parts by mass of a colorant are further added.

Step (1) specifically includes:
stirring the epoxy resin at 95° C. to 140° C. for 10 min to 180 min; adding the fused silica at 95° C. to 140° C., and further stirring a resulting mixture for 10 min to 180 min; and adding the curing system at a temperature lower than 40° C., and further stirring a resulting mixture for 10 min to 60 min.

When a colorant is added, the colorant is added simultaneously with the fused silica.

A mechanism of the present disclosure to enhance glossiness is as follows:

As shown in FIG. 1 and FIG. 2, a silicone main chain of glass epoxy in the film for protecting a chip of the present disclosure is not very compatible with the epoxy resin and thus migrates to a surface of the film; and the inorganic filler silica has a slightly-large particle size, which facilitates the glass epoxy to quickly migrate to the surface of the film, thereby improving the roughness of the surface of the film. The lower the roughness, the higher the glossiness. After the glass epoxy is cured, a reflective needle-like crystal can be produced on the surface of the film, which significantly improves the glossiness of the film.

Compared with the prior art, the present disclosure has the following characteristics and beneficial effects:

The glossiness of the protective film can be significantly improved, such that the clarity of characters inscribed by a laser under a bright field of a microscope can be further significantly improved, which allows a device to effectively recognize the characters.

### BRIEF DESCRIPTION OF THE DRAWINGS

FIG. 1 is a schematic diagram illustrating a microstructure of a traditional film for protecting a chip;

FIG. 2 is a schematic diagram illustrating a microstructure of the film for protecting a chip of the present disclosure;

FIG. 3 is a microphotograph of a surface of the film for protecting a chip in the comparative example;

FIG. 4 is a microphotograph of a surface of the film for protecting a chip in Example 1; and

FIG. 5 is a microphotograph of a surface of the film for protecting a chip in Example 2.

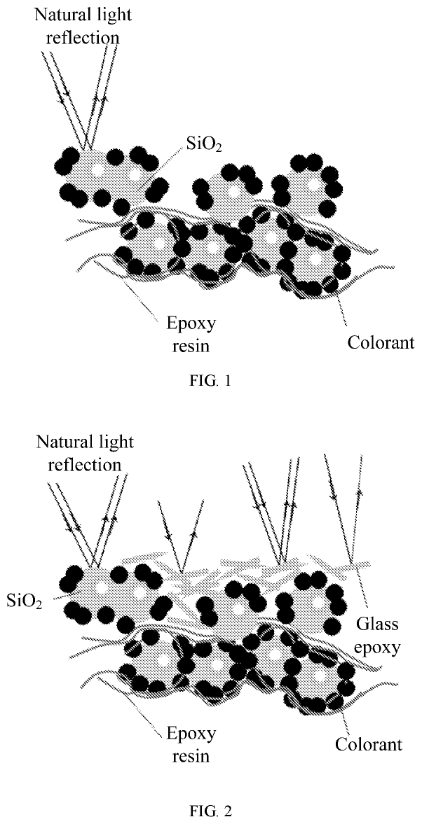

### DETAILED DESCRIPTION OF THE EMBODIMENTS

In order to make the objectives, technical solutions, and advantages of the present disclosure more comprehensible, specific implementations of the present disclosure are described in further detail below. It should be understood that the specific implementations described are merely intended to explain the present disclosure, rather than to limit the present disclosure.

The present disclosure provides a high-glossiness EMC film for protecting a chip, including: 40 to 100 parts by mass of an epoxy resin, 2 to 5 parts by mass of glass epoxy, 45 to 55 parts by mass of fused silica, and 1 to 5 parts by mass of a curing system, where the fused silica has a particle size D50 of 0.15 μm to 0.6 μm, preferably 0.27 μm to 0.60 μm, and further preferably 0.50 μm to 0.60 μm; and 1 to 5 parts by mass of a colorant can be optionally added.

The epoxy resin, as a host resin, is one or more selected from the group consisting of a polyether epoxy resin, a BPF epoxy resin, and a PU-modified BPA epoxy resin, and is preferably a polyether epoxy resin. The curing system is a curing system for the epoxy resin, including an accelerating agent and a curing agent. The curing agent is a curing agent corresponding to any epoxy resin, and can be one or more selected from the group consisting of an amine curing agent, a mercaptan curing agent, an anhydride curing agent, and a phenolic resin curing agent according to needs; and the accelerating agent is preferably an imidazole accelerating agent. The colorant is added to provide a color for the filler, and can be a pigment such as carbon black. The colorant is a non-essential component.

A specific preparation method of the high-glossiness EMC film for protecting a chip of the present disclosure is as follows:
step 1: the epoxy resin is added to a planetary stirrer, and stirred for 10 min to 180 min at 95° C. to 140° C.;
step 2: the fused silica and the colorant are added to the planetary stirrer, and a resulting mixture is further stirred for 10 min to 180 min at 95° C. to 140° C.;
step 3: the curing system is added to the planetary stirrer, and a resulting mixture is further stirred for 10 min to 60 min at a temperature lower than 40° C.;
step 4: the glass epoxy is added, and a resulting mixture is stirred, vacuumed by a vacuum pump until a negative pressure in a tank is lower than or equal to −0.95 Mpa, and then degassed until a resulting slurry in the tank is free of bubbles; and
step 5: the slurry is coated on a silicone oil-coated release film, and a resulting product is oven-dried to obtain the film for protecting a chip of the present disclosure.

In order to further prove the advantages of the film for protecting a chip of the present disclosure, the following contrast tests were conducted. In the following examples and comparative examples, the epoxy resin was a polyether epoxy resin and could be selected from the group consisting of Changshu Jiafa polyether epoxy resins Jef-0220, Jef-0211, and Jef-0221 on the market, a polyether epoxy resin SHIN-A SE-4125P, and a polyether epoxy resin Japan ADEKA EP-4000; the glass epoxy could be selected from the group consisting of glass epoxy with a molecular formula of CH₃Si(OCH₃)₃ of Nengqing Materials Co., Ltd. and a product X-40-2670 with a chemical formula of

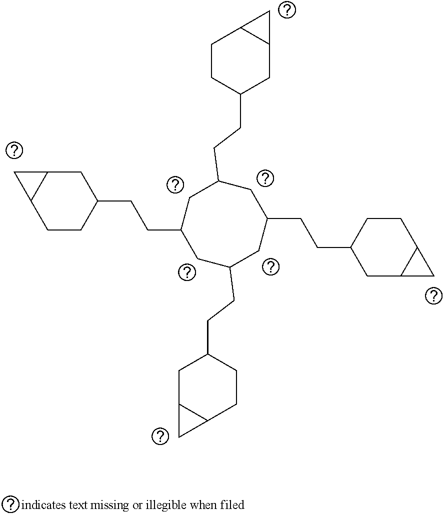 [SMILES: C(CC1CCC2CC2C1)C1CC(CCC2CCC3CC3C2)CC(CCC2CCC3CC3C2)CC(CCC2CCC3CC3C2)C1]

of Shin-Etsu Chemical Co., Ltd.; and the curing system was a mixture of 2-methyl-4-ethylimidazole and DCD.

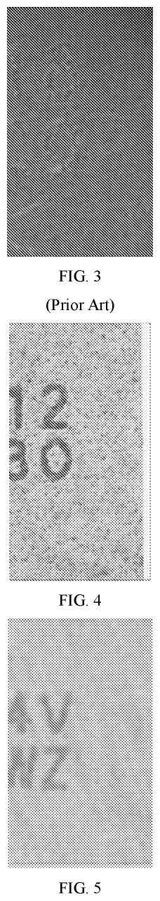

Compositions of the examples and comparative example were shown in Table 1, and a preparation method was the same as the specific preparation method described above. The products obtained in the examples and comparative example each were tested by a glossiness meter to determine 60° glossiness, and the glossiness was increased from 18 to 25 of the comparative example to 50 to 60 of the example, indicating a significant improvement; and characters inscribed by a laser were observed under a microscope, and observation results were shown in FIG. 3 to FIG. 5. It can be seen from the figures that characters on the film in the comparative example are blurred, and characters on the film of the example are very clear. It can be seen from the glossiness data and FIG. 3 to FIG. 5 that, when the large-particle-size silica and glass epoxy are used in combination, a film with excellent glossiness can be obtained, and characters inscribed on the film are clear.

TABLE 1
Compositions and test results of the examples and comparative example

| | | | Comparative |
|---|---|---|---|
| | Example 1 | Example 2 | Example |
| Polyether | 45 parts by mass | 45 parts by mass | 45 parts by mass |
| epoxy resin | | | |
| Glass epoxy | 2.2 parts by mass | 2.2 parts by mass | / |
| Silica | 50 parts by mass | 50 parts by mass | 50 parts by mass |
| Carbon black | 1.5 parts by mass | 1.5 parts by mass | 1.5 parts by mass |
| 2-Methyl-4- | 0.7 part by mass | 0.7 part by mass | 0.7 part by mass |
| ethylimidazole | | | |
| DCD | 2.7 parts by mass | 2.7 parts by mass | 2.7 parts by mass |
| Silica D50 | 0.56 μm | 0.27 μm | 0.56 μm |
| 60° glossiness | 50 to 60 | 40 to 50 | 18 to 25 |

The above examples are only some of various examples of the present disclosure. Changes or modifications in different forms can be made by those skilled in the art on the basis of the above description, and these changes or modifications derived from the essential spirit of the present disclosure still fall within the protection scope of the present disclosure.

What is claimed is:

1. A high-glossiness epoxy molding compound (EMC) film for protecting a chip, comprising the following components:
40 to 100 parts by mass of an epoxy resin;
2 to 5 parts by mass of a glass epoxy;
45 to 55 parts by mass of fused silica; and
1 to 5 parts by mass of a curing system,
wherein the fused silica has a particle size D50 of 0.15 μm to 0.6 μm.

2. The high-glossiness EMC film for protecting the chip according to claim 1, wherein the fused silica has the particle size D50 of 0.27 μm to 0.6 μm.

3. The high-glossiness EMC film for protecting the chip according to claim 1, wherein
the epoxy resin is one or more selected from the group consisting of a polyether epoxy resin, a bisphenol F (BPF) epoxy resin, and a polyurethane (PU)-modified bisphenol A (BPA) epoxy resin.

4. The high-glossiness EMC film for protecting the chip according to claim 1, wherein
the curing system comprises an accelerating agent and a curing agent, wherein the curing agent is one or more selected from the group consisting of an amine curing agent, a mercaptan curing agent, an anhydride curing agent, and a phenolic resin curing agent, and the accelerating agent is an imidazole accelerating agent.

5. The high-glossiness EMC film for protecting the chip according to claim 4, wherein
the accelerating agent is used in 0.1 to 1 part by mass and the curing agent is used in 1 to 4 parts by mass.

6. The high-glossiness EMC film for protecting the chip according to claim 4, wherein
the curing agent is dicyanodiamide (DCD), and the accelerating agent is 2-methyl-4-ethylimidazole.

7. The high-glossiness EMC film for protecting the chip according to claim 1, further comprising:
1 to 5 parts by mass of a colorant.

8. A preparation method of the high-glossiness EMC film for protecting the chip according to claim 1, comprising:
(1) mixing 40 to 100 parts by mass of the epoxy resin, 45 to 55 parts by mass of the fused silica, and 1 to 5 parts by mass of the curing system, and stirring a first resulting mixture, wherein the fused silica has a particle size D50 of 0.15 pin to 0.6 pin;
(2) adding 2 to 5 parts by mass of the glass epoxy, stirring a second resulting mixture, and degassing the second resulting mixture until a resulting slurry is free of bubbles; and
(3) coating the resulting slurry on a release film, and oven-drying a resulting release film.

9. The preparation method of the high-glossiness EMC film for protecting the chip according to claim 8, wherein
in step (1), 1 to 5 parts by mass of a colorant are further added.

10. The preparation method of the high-glossiness EMC film for protecting the chip according to claim 8, wherein
step (1) specifically comprises:
stirring the epoxy resin at 95° C. to 140° C. for 10 min to 180 min; adding the fused silica in the epoxy resin at 95° C. to 140° C., and further stirring a third resulting mixture for 10 min to 180 min; and adding the curing system in the third resulting mixture at a temperature lower than 40° C. to obtain the first resulting mixture, and further stirring the first resulting mixture for 10 min to 60 min.
